(19) United States
(12) Patent Application Publication
(10) Pub. No.: US 2023/0383396 A1
(43) Pub. Date: Nov. 30, 2023

(54) CARBON DOPED METAL OXYFLUORIDE (C:M-0-F) LAYER AS PROTECTION LAYER IN FLUORINE PLASMA ETCH PROCESSES

(71) Applicant: Oerlikon Surface Solutions AG, Pfäffikon, Pfäffikon (CH)

(72) Inventors: Siegfried KRASSNITZER, Feldkirch (AT); Sebastien GUIMOND, St. Gallen (CH); Julien KERAUDY, Buchs (CH); John CONIFF, Queen Creek, AZ (US); Matthew Paul KIRK, Lockport, NY (US)

(21) Appl. No.: 18/248,894

(22) PCT Filed: Oct. 19, 2021
(86) PCT No.: PCT/EP2021/078906

§ 371 Date: Apr. 13, 2023

(30) Foreign Application Priority Data
Oct. 19, 2020 (DE) 10 2020 006 407.8

(51) Int. Cl. C23C 14/08; C23C 16/40; C23C 16/455; C23C 28/04; C23C 16/02

(52) U.S. Cl. CPC C23C 14/083; C23C 16/405; C23C 16/45595; C23C 28/042; C23C 16/0272

(57) ABSTRACT

An article including: a substrate; and a protective film overlaying at least part of the substrate, the film including a fluorinated metal oxide, containing one or more elements of the Group III and/or Group IV elements of the periodical system of elements, characterized in that the protective film includes the fluorinated metal oxide with a carbon doping with a carbon concentration not lower than 0.1 at % and not higher than 10 at %, preferably not lower than 0.5 at % and more preferably not higher than 2.5 at %, wherein the article is a plasma etch chamber component and/or part and preferably an article of the group formed by electrostatic chuck, a ring, a process kit ring, a single ring, a chamber wall, a shower head, a nozzle, a lid, a liner, a window, a baffle or a fastener.

Halogen-containing-plasmas (fluorine, chlorine, bromide, iodine) have been extensively used in the semiconductor industry in order to etch silicon wafers. However, the halogen-containing plasmas also bombard and erode the parts and components of the plasma etching chambers, while the resultant particles may contaminate the wafers resulting in lowering device yields and shortening the lifetime of the parts and components of the plasma etching chambers which ultimately leads to increased process downtime and greater expense of producing semiconductor devices.

In order to protect the devices from erosion, corrosion and the formation of contaminants, many oxide ceramics, such as Al2O3, AlON or Y2O3, are used as anti-plasma-etching component protective materials and coatings. One of the conventional plasma-resistant ceramics is Yttria (Y2O3). It has demonstrated longer chamber lifetime under plasma for both metal etch and dielectric silicon-based etch applications because of its higher plasma erosion and corrosion resistance in comparison to other oxide-based ceramics.

However, when using Y2O3 as an etch protection layer in fluorine-containing plasma it has been reported that the Fluorine plasma reacted with the Y2O3 layer forming an altered YOF surface layer. This YOF layer has the tendency to peel off and generate particles which give rise to surface contamination on the wafers to be etched. This ultimately leads to reduction of production yield and strong difficulty to achieve high-level of process reproducibility for the integrated circuits.

Kazuhiro et al in J. Vac. Sci. A 27(4), July/August 2009 explain the formation of YOF to happen in four steps. According to the first step a fluorocarbon film is formed on the Y2O3 surface. According to the second step Carbon of the Fluorocarbon film and Oxygen of the Y2O3 react to form volatile CO. Thereby Y—O bondings are decomposed. According to the third step Yttrium of the decomposed Y—O bondings reacts with the Fluorine of the fluorocarbon film and therefore YOxFy and/or YFx bondings are formed.

In order to avoid this problem prior art proposes to deposit an etch resistant yttrium oxyfluoride Y—O—F (YxOyFz) coating to prevent the third step and acting as a protective layer to prevent the coating surface from further erosion by fluorine plasma and particle generation. However despite being chemically inert with respect to F, the YOF coating as well can undergo degradation due to the deposition of fluorocarbon polymer layers by the adsorption of fluorocarbon radicals on the YOF surface. Among other drawbacks these layers influence the etching processes and can produce large and uncontrolled shifts.

Thus, there is a need for an improved coating having superior plasma etch-resistance and offering high-level of process stability and reproducibility for the production of integrated circuits. In many cases seasoning and conditioning is used to improve such stability and reproducibility. However, this can be time consuming and can heavily increase the cost of production.

The present invention has the objective to solve the problem as described above and to provide an improved coating for process chamber parts, having a superior plasma etch-resistance and offering high-level of process stability and reproducibility for fluorine plasma based etch processes for the production of semiconductor devices. The present invention has as well the objective to provide a method for producing such an improved coating.

According to the present invention the problem is solved by an article according to the independent claim 1, wherein the article may preferably be formed as a vacuum compatible plasma etch chamber article, comprising a vacuum compatible substrate. The dependent claims describe further and preferred embodiments of the present invention.

According to the present invention, the article comprises an improved coating, wherein the improved coating may be formed as a thin film comprising fluorinated metal oxide, wherein the thin film in addition comprises carbon with a concentration being in the range from 0.1 at % to 10 at %, preferably between 0.5 at % and 2.5 at %. The metal of the fluorinated metal oxide may be one or more element of the group III and or group IV elements of the periodical system. More preferably the metal may contain Yttrium or may be Yttrium.

According to another example, the protective film may comprise a gradient layer with increasing fluorine concentration measured from a deeper part of the protective film to a less deep part of the protective film and/or the protective film may be a multilayer system comprising at least two layers with different fluorine concentrations with the fluorine concentration in the layer more distant to the substrate being higher than the fluorine concentration in the layer closer to the substrate.

According to a preferred embodiment of the present invention the thin film is a MaObFcCd film with 0.25<a<0.4, 0.2<b<0.6, 0.1<c<0.6 and 0.01<d<0.1 with a+b+c+d=1 if only these materials in the film are taken into account. This means that additional materials may be as well present in the film. However it is preferred that the concentration of each of the additional materials does not exceed 5 at %. Most preferably no additional materials apart from difficult to avoid pollutions are present in the film.

According to another aspect of the present invention a method for producing an article according to the invention is disclosed, wherein the protective film overlaying at least a part of the substrate is applied by Physical Vapor Deposition (PVD) and/or Chemical Vapor Deposition (CVD). The inventive film hereby is to be applied on chamber parts/components for use in semiconductor production equipment by Physical Vapor Deposition (PVD) and/or Chemical Vapor Deposition (CVD) such as for example Plasma Enhanced CVD. The inventive film is most suited for being applied on Aluminum and/or oxidized Aluminum and/or anodized Aluminum and/or precoated Aluminum and/or precoated anodized aluminium parts. One example would be the deposition of a thermal spray Y2O3 precoat layer onto anodized aluminum. Other substrates, such as for example quartz are possible as well.

The inventive film can comprise or be a graded layer, starting from pure Metaloxide (Me—O) on the substrate to Me—O—F—C as top layer. The film can as well be a two or multilayer system, preferably with increasing F and/or C concentration in direction to the surface.

The inventive film can comprise one or more metal and/or metal oxide layer(s) as an adhesion-promoting means to the substrate.

Preferably the inventive film has a hardness of at least 10 GPa as determined by nanoindentation.

Preferably the inventive film has a thickness between 0.1 μm and 30 μm.

According to one embodiment, the inventive film has an amorphous phase, however according to a preferred embodiment the inventive film has crystalline phase such as for example trigonal and/or orthorhombic and/or preferably a rhombohedral crystalline phase as determined by x-ray diffraction.

According to a preferred embodiment the inventive film has a roughness of Ra<1 μm, preferably Ra<0.25 μm, most preferably Ra<0.025 μm.

According to a preferred embodiment the inventive film has a reduced peak height of Rpk<0.25 μm, preferably Rpk<0.10 μm, most preferably Rpk<0.025 μm.

The inventive film can for example be produced by plasma vapor deposition (PVD) process, preferably a reactive sputter process for example pulsed DC and/or HiPIMS and or bipolar HiPIMS and/or modulated pulsed power magnetron sputtering (MPPS). If a reactive process is used the reactive gas can be for example a mixture of CF-containing gases (such as CF4, C2F6, C3F8, etc. . . . ) with oxygen-containing gases (such as O2). The target can be a pure metallic target. It can be however as well for example a ceramic target, such as for example oxide, preferably Y2O3 and/or fluoride, preferably YF3 or a mixture thereof. A PVD process is particularly suitable, since the inherent density and lack of porosity of PVD films compared to existing art (thermal spray, aerosol deposition) particularly contributes positively to the reduction of particulate formation.

It can be advantageous to use a substrate bias which is floating and/or DC and or pulsed DC and/or bipolar and/or RF.

It can well be advantageous to use a Y-containing thermally sprayed precoat such as but not limited to Y2O3 and/or YOF layer.

Application examples are chamber components including but not limited to an electrostatic chuck (ESC), a ring (e.g. a process kit ring or single ring), a chamber wall, a showerhead, a nozzle, a lid, a liner, a window, baffle, fastener.

Preferably during the coating the substrate temperature is kept below 180° C., and most preferably below 150° C. It should be noted that with higher temperature a higher deposition rate can be realized, however sometimes the substrates have temperature restrictions.

The invention is now described in detail on the basis of an example and with the help of the figures.

The figures show the following:

FIG. 1 shows the material composition of the films resulting from the two coating runs.

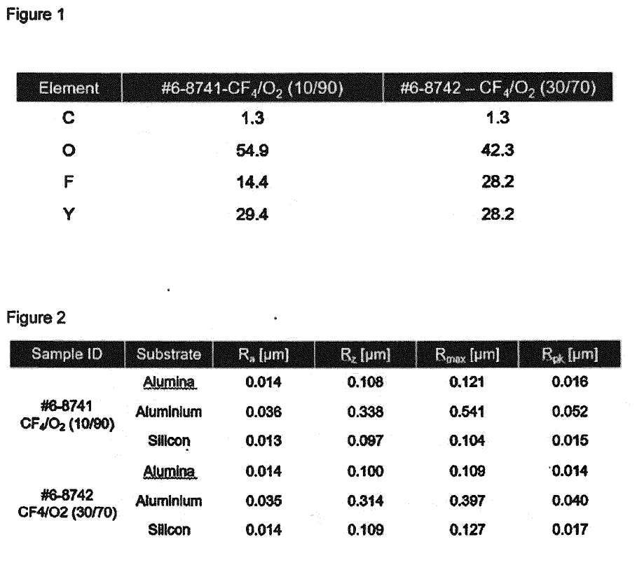

FIG. 2 shows different roughness values of the films coated on alumina, aluminum and silicon.

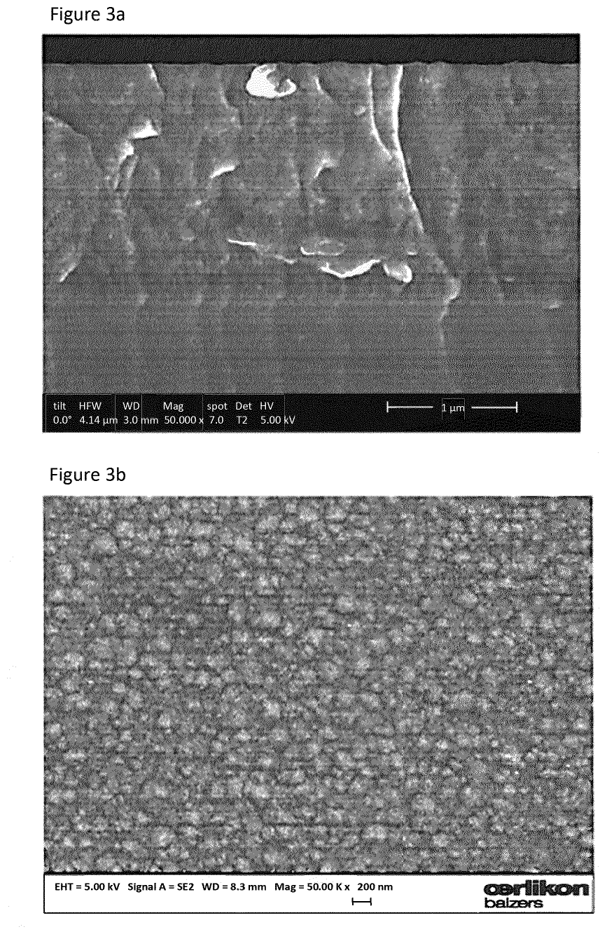

FIG. 3a shows the SEM of a cross section of a sample.

FIG. 3b shows the SEM of a part of the surface of a sample.

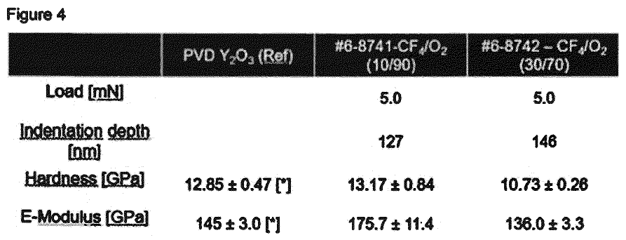

FIG. 4 shows the measured hardness and the E-modulus of the films resulting from the two coating runs.

In a first coating run aluminum and alumina (4μ-in. Ra) as well as silicon substrates were solvent cleaned and loaded onto a 2-axis of rotation planetary system inside a stainless-steel deposition system.

Argon plasma etching of substrates was performed using a DC filament discharge and pulsed DC substrate biasing.

The chamber was evacuated below 1E-2 mbar and an Argon flow regulated to 160 sccm was established.

Pulsed DC power was then delivered to a balanced planar Yttrium target starting at a 50% power setting and then ramping to 6 kW.

Reactive gasses O2 and CF4 were then used to deposit the C doped Yttrium Oxyfluoride (YOFC) coating. The ratio of CF4 to O2 was set to a ratio of 30:70. The reactive gasses are then adjusted at this set ratio slowly over a period of 5 min. so that the cathode voltage decreases steadily from 565V (pure metal film) to a final set point of 380V (fully oxy-fluoride doped carbon film). At this point the CF4/O2 ratio is still fixed. Minor adjustments in gas flow maintains the operating voltage setpoint on the sputtering cathode for the duration of the deposition. The conditions are thereby held at constant until the desired thickness of 2 μm is reached for the YOF functional top layer of the coating.

A second coating run was performed. All parameters but the CF4 to O2 ratio were the same as in the first coating run. The CF4 to O2 ratio was set to a ratio of 10:90.

FIG. 1 shows the resulting coating compositions for both coating runs determined by ERDA/RBS analysis. Coating composition is given in atomic ratio at. %. The detection limit is below 0.1 at. %. It can be seen that the C concentration is at 1.2 at % for both coatings. In contrast oxygen concentration goes down and fluorine concentration goes up if CF4/O2 ratio is increased.

XRD measurements revealed a rhombohedral crystalline structure of the coating.

Roughness measurements were performed on these with a stylus profilometer. The results are shown in FIG. 2. The inventive films seem to provide very small roughness values which might help to decrease the flaking effect. Remarkable as well are the small Rpk (reduced peak height) values. The coating surface does not provide for a topology with extraordinary peaks, it more resembles a hilly landscape. This as well can be seen from the SEM picture in FIG. 3b, taken as top view. FIG. 3a shows an SEM of a cross section of one of the samples.

The inventors performed as well hardness measurements on their samples which were carried out on a UNAT equipment (Universal Nanomechanical Tester). Hardness might insofar at least indirectly play a role as harder films have typically a higher density and are therefore less prone to be etched. The films were indented 45 times using a fixed load of 5 mN, while indentation depths are maintained below 10% of film thickness (Oliver and Pharr method rule). FIG. 4 shows the respective measurements.

Hardness and E-Modulus turned out to be in the same range as compared to prior art Y2O3 films, taken as reference.

What is claimed is:

1. An article comprising
a substrate
a protective film overlaying at least part of the substrate, the film comprising a fluorinated metal oxide, containing one or more elements of the Group III and/or Group IV elements of the periodical system of elements, characterized in that the protective film comprises the fluorinated metal oxide with a carbon doping with a carbon concentration not lower than 0.1 at % and not higher than 10 at %, wherein the article is a plasma etch chamber component and/or part.

2. Article according to claim 1, characterized in that the metal of the protective film contains Yttrium.

3. Article according to claim 1, characterized in that the protective film has a coating thickness not less than 0.1 μm and not more than 30 μm.

4. Article according to claim 1, characterized in that the protective film has a roughness of Ra<1 μm.

5. Article according to claim 1, characterized in that the protective film has a reduced peak height of Rpk<0.25 μm.

6. Article according to claim 1, characterized in that the protective film has a hardness of at least 10 GPa as determined by nanoindentation with a fixed load of 5 mN, while the indentation depth is maintained below 10% of the coating thickness.

7. Article according to claim 1, characterized in that between the protective film and the substrate is an adhesion-promoting layer being a second metal or second metal oxide, where the metal of the film and second metal are identical.

8. Article according to claim 1, characterized in that the protective film comprises a gradient layer with increasing fluorine concentration measured from a deeper part of the protective film to a less deep part of the protective film and/or the protective film is a multilayer system comprising at least two layers with different fluorine concentrations with the fluorine concentration in the layer more distant to the substrate being higher than the fluorine concentration in the layer closer to the substrate.

9. Article according to claim 1, characterized in that the protective film comprises a gradient layer starting close to the substrate from pure M2O3 to (MaObFcCd), in which the concentration of MaObFcCd are chosen as follows: 0.25<a<0.4, 0.2<b<0.6, 0.1<c<0.6 and 0.01<d<0.1 with a+b+c+d=1.

10. Article according to claim 1, characterized in that between the protective film or if given the adhesion promoting layer and the substrate foreseen is a Y-containing thermally sprayed precoat, comprising Y2O3 and/or YOF.

11. Method for producing an article according to claim 1, characterized in that the protective film overlaying at least a part of the substrate is applied by Physical Vapor Deposition (PVD) and/or Chemical Vapor Deposition (CVD).

12. Article according to claim 1 wherein the carbon concentration is not lower than 0.5 at %.

13. Article according to claim 12 wherein the carbon concentration is not higher than 2.5 at %.

14. Article according to claim 1 wherein the carbon concentration is not higher than 2.5 at %.

15. Article according to claim 1 wherein the article is at least one of an electrostatic chuck, a ring, a process kit ring, a single ring, a chamber wall, a shower head, a nozzle, a lid, a liner, a window, a baffle, or a fastener.

16. Article according to claim 1, characterized in that the metal of the protective film is Yttrium.

17. Article according to claim 1, characterized in that the protective film has a roughness of Ra<0.25 μm.

18. Article according to claim 1, characterized in that the protective film has a roughness of Ra<0.025 μm.

19. Article according to claim 1, characterized in that the protective film has a reduced peak height of Rpk<0.10 μm.

20. Article according to claim 1, characterized in that the protective film has a reduced peak height of Rpk<0.025 μm.
